(19) United States
(12) Patent Application Publication
(10) Pub. No.: US 2005/0152116 A1
(43) Pub. Date: Jul. 14, 2005

(54) Methods and apparatus for passive cooling of electronic units

(76) Inventor: Charles R. McClary, Spring Lake Park, MN (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/755,775

(22) Filed: Jan. 12, 2004

(51) Int. Cl. H05K 7/20

(52) U.S. Cl. 361/704; 361/735; 165/80.4

(57) ABSTRACT

A cooling apparatus for an electronic unit is described which includes a first plate, a second plate, and a controlling mechanism. The first and second plates are generally planar and have holes formed therethrough. The controlling mechanism is operable to move the first plate with respect to the second plate. A first position for movement is where more of the holes in the first plate and the second plate are substantially aligned than are not aligned. A second position is where more of the holes in the first plate and the second plate are not aligned than are aligned.

### BACKGROUND OF THE INVENTION

This invention relates generally to controlling temperatures within operating electronic units, and more specifically, to methods and apparatus for cooling of electronic units.

Typical electronic equipment rack installations, for example, those used in the mounting of various electronic equipment in aircraft, are sometimes designed for forced air cooling, the forced air being blown through the electronic unit. However, forced air cooling of electronic units also typically means that a chassis of the electronic unit is configured with one or more vents which allow for the ingress and egress of the forced air. However, such electronic units are sometimes utilized in harsh environments, where numerous fluids (i.e., hydraulic fluids, fuel, water) may be present. These vents which facilitate the forced air cooling may also be a point of ingress for these fluids. The fluids may be detrimental to the circuits within the chassis of the electronic unit.

In electronic units that are not cooled through forced air cooling, a chassis may be substantially sealed to try to prevent ingress of the above described fluids. Such a chassis is sometimes configured with fins on one or more sides of the chassis, facilitating cooling through radiation of the heat through the fins. Such a chassis is typically painted black or with some other high emissivity coating to maximize passive cooling through radiation. While substantially impervious to the fluids, such a chassis is sometimes inefficient at cooling. For example, other electronic equipment operating in the vicinity may be operating at approximately the same temperature, limiting cooling through radiation of heat from the fins.

Easy removal and replacement of electronic units, for example, in air vehicles, is also a consideration. Present electronic equipment installations include features and mechanisms that provide for easy removal and replacement of electronic units in the example equipment rack installations.

### BRIEF SUMMARY OF THE INVENTION

In one aspect, a cooling apparatus for an electronic unit is provided that comprises a generally planar first plate having holes formed therethrough, a generally planar second plate having holes formed therethrough, and a controlling mechanism. The controlling mechanism is operable to move the first plate with respect to the second plate, operable to cause the first plate to move to a first position where more holes in the first plate and the second plate are substantially aligned than not aligned, and further operable to cause the first plate to move to a second position where more holes in the first plate and the second plate are not aligned than are aligned.

In another aspect, a chassis for an electronic unit is provided which comprises a top having a pattern of holes formed therethrough. The chassis also comprises a generally planar plate movably mounted with respect to the top of the chassis. The plate is substantially parallel to the top and has holes formed therethrough.

In yet another aspect, a method for constructing a chassis for an electronic unit that is compatible for active cooling, passive cooling and protected from ingress of fluids is provided. The method comprises forming holes in a top of the chassis, forming holes in a plate, and movably mounting the plate above, and substantially parallel to the top of the chassis. The mounting includes at least one position where more of the holes in the plate and the top substantially align with one another than do not align and at least one position where more of the holes do not substantially align with one another than do substantially align.

### BRIEF DESCRIPTION OF THE DRAWINGS

FIG. 1 is a side view of an electronic unit mounted on a mounting rack utilizing forced air cooling.

FIG. 2 is a side view of an electronic unit mounted on a mounting rack, the electronic unit including a shuttering mechanism in the open position.

FIG. 3 is a top view of the electronic unit of FIG. 2.

FIG. 4 is a side view of the electronic unit of FIG. 2 showing the shuttering mechanism in a closed position.

FIG. 5 is a top view of the electronic unit of FIG. 4.

FIG. 6 is a side view of an electronic unit mounted on a mounting rack, illustrating an actuator utilized to move a shuttering mechanism.

FIG. 7 is an end cross-sectional view of the electronic unit of FIG. 6.

### DETAILED DESCRIPTION OF THE INVENTION

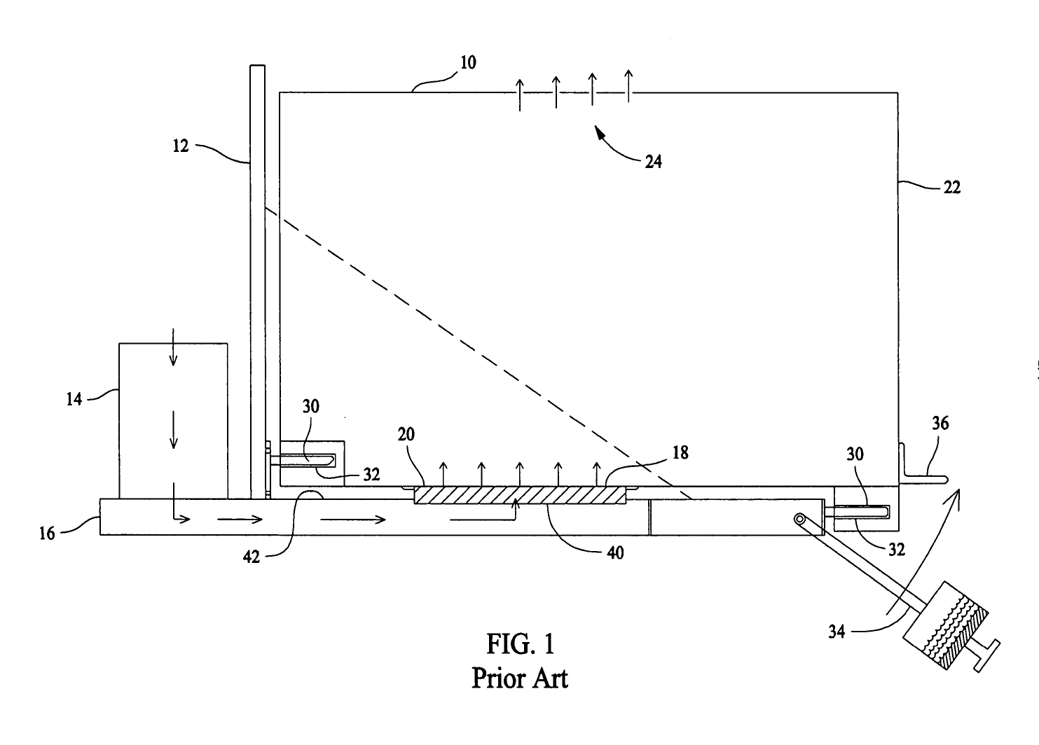

FIG. 1 is a diagram of an electronic unit 10 mounted on a mounting rack 12. Electronic unit 10 utilizes forced air cooling and mounting rack 12 is configured with features which accommodate forced air cooling. Mounting rack 12 includes an air plenum 14 and a hollow frame portion 16. As shown, mounting rack 12 is configured such that electronic unit 10 can be mounted thereto. As used herein, mounting rack 12 also includes shelves which do not include air plenums 14 and hollow frame portions 16, but which have suitable mounting features for the mounting of electronic units 10.

A hollow frame portion 16 of frame 12 is hollow so that cooling air (depicted by the arrows) from a cooling air source (not shown) can be routed to plenum 14, through hollow frame portion 16, and into electronic unit 10 at cooling air interface 18. Electronic unit 10 which is attached to frame 12 includes holes in a bottom 20 of its chassis 22 which align with cooling air interface 18. The cooling air passes through electronic unit 10 and eventually exits electronic unit 10, for example, at air exit 24, carrying at least some of the heat generated by operation of electronic unit 10. However, in some electronic units similar to electronic unit 10 it is desirable to prevent, or at least reduce, fluid entry into the unit. Air exit 24 may be a point of entry for fluids, should fluids be present in the vicinity of electronic unit 10.

Other electronic units are known to exist, some of which do not utilize forced air cooling. Some of these units are sometimes referred to as being passively cooled. These units may be configured with a chassis with holes, or other features that allow heat to dissipate through convection or radiation. It may be desirable to operate some of these units in the presence of the above described fluids.

For precise alignment, which is necessary with some electronic units 10, mounting rack 12 further includes guide pins 30 which engage mounting bores 32 formed in chassis 22 of electronic unit 10. Mounting rack 12 also includes one or more pivotably attached threaded retention clips 34 which engage tangs 36 extending from chassis 22 of electronics unit and help to retain electronic unit 10 on mounting rack 12. Mounting rack 12 is representative of several types of electronic equipment mounting devices which utilize forced air cooling in that they employ an interface to a forced air system (e.g. plenum 14) and that the device be configured to route the cooling air to specific locations to enter the electronics unit to be cooled. The interface to the cooling air, plenum 14, and the “ducting” (e.g. hollow frame portion 16) within the mounting devices add cost, weight, and take away from what is typically an already small area in many installations.

In certain applications, for example, when electronic unit 10 is a type of inertial reference unit, guide pins 30 and mounting bores 32 are precision machined so that electronic unit 10 is retained in a specific orientation on mounting rack 12. Additionally, and in other applications, cooling air interface 18 includes a gasket 40 which helps to prevent cooling air from escaping from the desired path into electronic unit 10. Similar to mounting rack 12, certain shelves which do not use cooling air, but utilize guide pins 30 and mounting bores 32 are known. With such shelves and mounting racks, a chassis of an electronic unit is again largely prevented from making contact with any surfaces of the shelves, also reducing an amount of conductive cooling. In addition, air exit 24, can sometimes make electronics unit 10 susceptible to ingress of fluids, for example, water, and hydraulic fluids that are sometimes used in movement of control surfaces of an aircraft.

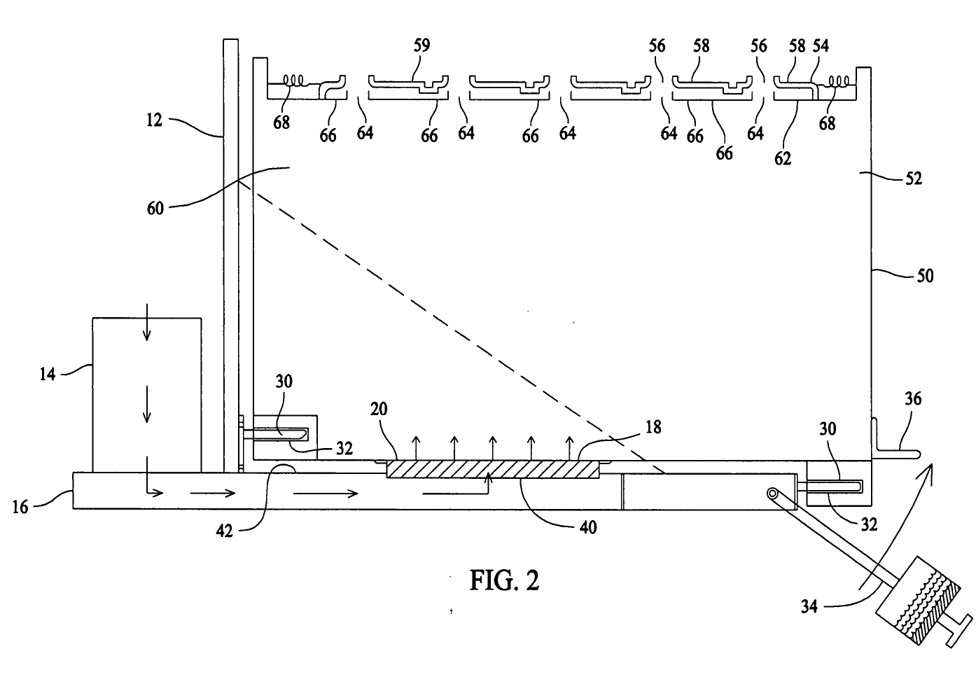

FIG. 2 illustrates an electronic unit 50 having a chassis 52 that is configured for both forced air cooling and passive cooling. Chassis 52 also provides some protection against ingress of fluids. A movable plate 54 on top of chassis 52 is configured with a plurality of holes 56 which are formed inside protrusions 58 which generally extend upward from a top 59 of top plate 54. Chassis 52 forms an interior 60 and further includes a fixed plate 62 that is situated below and generally planar with respect to top plate 54. In one embodiment, and as shown, fixed plate 62 forms a top of chassis 52. Fixed plate 62 is also configured with holes 64 and protrusions 66. In a specific embodiment, and as illustrated in the Figures, top plate 54 and fixed plate 62 are configured with substantially similar hole patterns. Top plate 54 is movable with respect to fixed plate 62 such that holes 56 and 64 can be aligned providing an exit for forced air and/or passively convected heat from electronic unit 50. A spring mechanism 68 is utilized to adjust a position of top plate 54 upon chassis 52. In alternative embodiments, spring mechanism 68 is either activated manually by a user, for example, a flight technician or automatically. Examples of such controlling mechanisms include, but are not limited to, mechanical levers, spring-loaded devices, and an electrical switch. Other controlling mechanisms are signal based, for example, solenoids and temperature controlled devices.

Protrusions 58 and 66 help to reduce incidence of fluid incursion since holes 56 and 64 are generally above chassis 52. Unless the amount of fluid is substantial, protrusions 66 will allow fluids to flow over a side wall (not shown) of chassis 52 before an amount that would be able to enter holes 64 can build up on top 62.

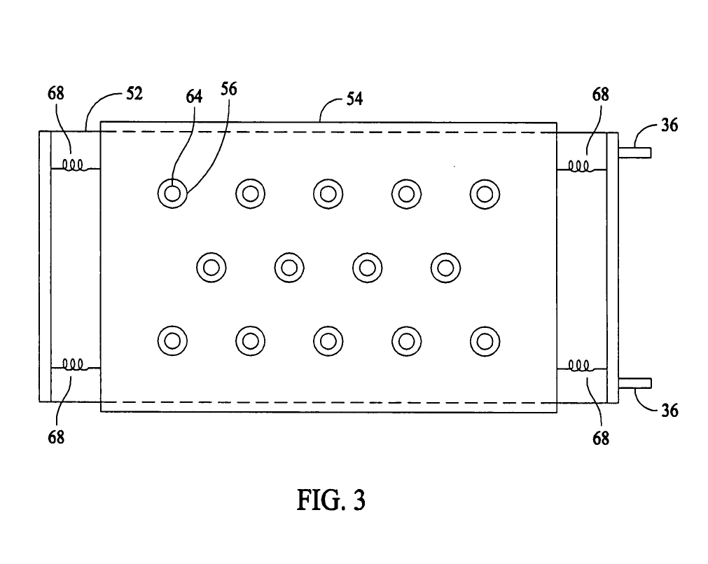

FIG. 3 is a top view of chassis 52 illustrating that holes 64 of fixed plate 62 are aligned with holes 56 of movable plate 54. Spring mechanism 68 connections to movable plate 54 are also illustrated. Movable plate 54 and fixed plate 62 are sometimes collectively referred to as a shuttering mechanism.

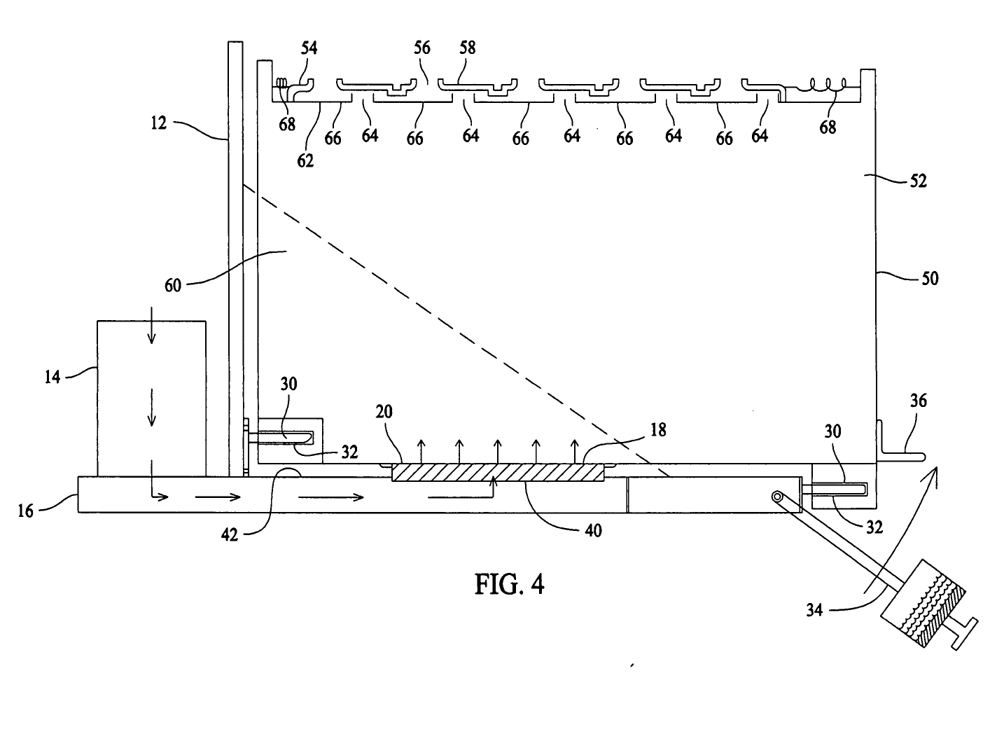

FIG. 4 illustrates electronic unit 50 where movable plate 54 has been moved relative to fixed plate 62 of chassis 52 such that the plurality of holes 56 which are formed inside protrusions 58 are not aligned with holes 64 and protrusions 66 of fixed plate 62. Since holes 56 and holes 64 are not aligned, protection from ingress of fluids is increased. For example, any fluid that manages to pass through holes 56 will likely land on fixed plate 62. Protrusions 66 help to ensure that any fluids on fixed plate 62 likely will not pass into interior 60 of chassis 52. Fixed plate 62 may also be configured so that any fluids landing thereon are routed to flow over a side wall (not shown) of chassis 52.

The non-alignment of holes 56 and 64 however lessens effects of passive cooling since heat has to travel from interior 60, through holes 64 of fixed plate 62, turn, move laterally until aligned with holes 56 and out of chassis 52 through movable plate 54. However, with movable plate 54 in such a position, cooling through forced air cooling is still relatively efficient, and the non-alignment of holes 56 and 64 presents minor resistance to air flow. Again, spring mechanism 68 is utilized to adjust a position of movable plate 54 relative to fixed plate 62 either manually by a user, for example, a flight technician, or automatically through an electromechanical (e.g., signal based) device such as those described above.

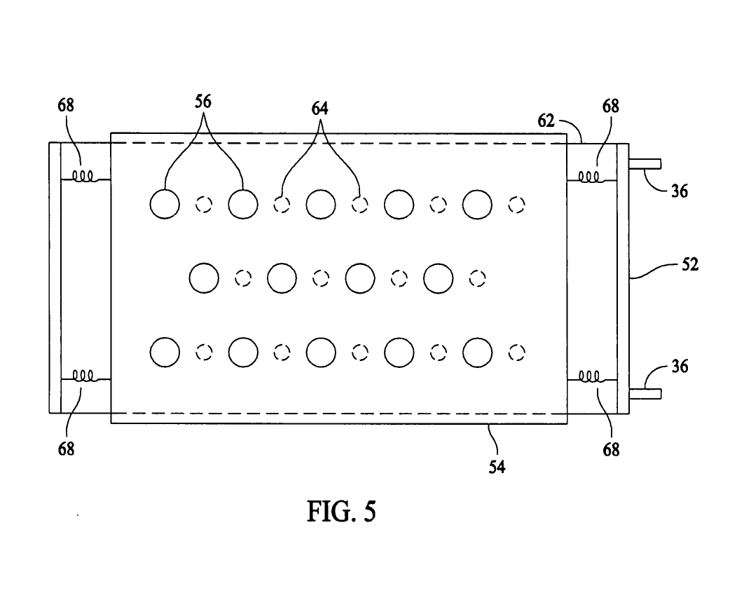

FIG. 5 is a top view of chassis 52 illustrating that holes 64 (shown in hidden view) of fixed plate 62 are not aligned with holes 56 of movable plate 54. As used herein, not aligned describes a position where substantially none of an individual hole 56 overlaps any portion of an individual hole 64 as viewed from above. In an alternative embodiment, the above described shuttering mechanism is fitted onto an existing chassis. In such an embodiment, fixed plate 62 and movable plate 54 are fitted onto and above a top of such an existing chassis, and provide the functionality as described above.

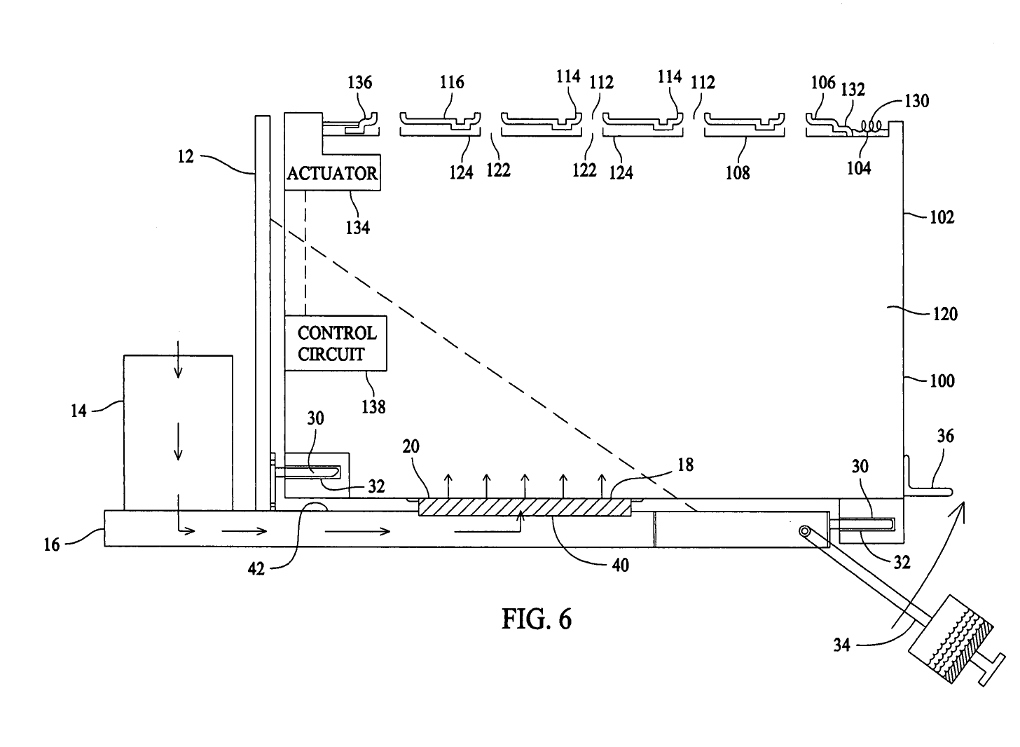

FIG. 6 illustrates an electronic unit 100 having a chassis 102, a chassis top 104, a movable first plate 106 substantially planar with chassis top 104, and a fixed second plate 108 substantially planar with first plate 106. Fixed second plate 108 forms a portion of chassis top 104, in the embodiment shown. Electronic unit 100 is configured for forced air cooling and additionally configured for passive cooling along with providing some protection against ingress of fluids. As described further below, movable first plate 106 is configured similarly to movable plate 54 of chassis 50 (both shown in FIGS. 2-5) and fixed second plate 108 is configured similarly to fixed plate 62 (shown in FIGS. 2-5).

Referring to first plate 106, a plurality of holes 112 are formed inside protrusions 114 which generally extend upward from a top 116 of first plate 106. In an interior 120 of chassis 102, and below first plate 106, a fixed second plate 108 is situated substantially planar with first plate 106. Second plate 108 is also configured with holes 122 and protrusions 124 similar to first plate 106. First plate 106 is movable with respect to second plate 108 such that holes 112 and 122 can be aligned providing an exit for forced air and/or passively convected heat from electronic unit 100. A spring mechanism 130 is utilized in adjusting a position of first plate 106 upon top 104 of chassis 102. Specifically, spring mechanism 130 is attached to a first end 132 of first plate 106. Opposite spring mechanism 130, a solenoid 134 is attached to a second end 136 of first plate 106. Solenoid 134 is further attached to chassis 102 within its interior 120. In the embodiment shown, solenoid 134 is controlled by a control circuit 138 within chassis 102. In a particular embodiment, control circuit 138 is a temperature sensitive circuit.

In alternative embodiments, solenoid 134 is activated manually (e.g. a switch) by a user, for example, a flight technician. Alternatively, control circuit 138 may be located remote from chassis 102. Embodiments other than solenoid 134 for moving first plate 106 with respect to second plate 108 are contemplated, including, but not limited to, other temperature controlled mechanisms, manually controlled mechanisms, and electrically controlled mechanisms.

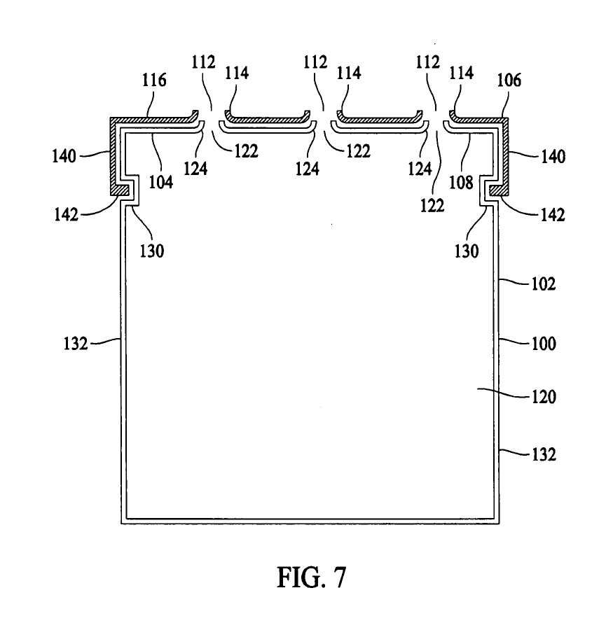

FIG. 7 is an end cross-sectional view of electronic unit 100 of FIG. 6. As described above, electronic unit 100 includes chassis 102, chassis top 104, movable first plate 106, and fixed second plate 108 substantially planar with movable first plate 106. A plurality of holes 112 are formed inside protrusions 114 which generally extend upward from a top 116 of first plate 106. In an interior 120 of chassis 102, and below first plate 106, second plate 108 is also configured with holes 122 and protrusions 124. As shown, movable first plate 106 is free to move relative to fixed second plate 108 in one direction and is constrained in the other two orthogonal directions. To facilitate such movement, chassis 102 is configured with channels 130 formed in sides 132 of chassis 102. Movable first plate 106 includes side walls 140 which terminate in inward facing protrusions 142, which are sized to engage channels 130 in chassis 102. When moving first plate 106 with respect to second plate 108, channels 130 and inward facing protrusions 142 form a guide to constrain the movement of first plate 106 along the plane of chassis top 104.

Similar to those described above with respect to FIGS. 2-5, protrusions 114 and 124 help to reduce incidence of fluid incursion since holes 112 and 122 are generally in first plate 106 and second plate 108 respectively. Unless the amount of fluid is substantial, protrusions 114 and 124 will cause fluids to gather on the tops of first plate 106 and second plates 108 and run off a side (not shown) of chassis 102 before any of the fluids will enter into interior 120 of chassis 102. First plate 106 and second plate 108 are sometimes collectively referred to as a shuttering mechanism.

The above described embodiments of shuttering mechanisms provide the benefits of both passive cooling and forced air cooling in a single device design. Holes in the bottoms and tops of the described chassis allow air to be forced through the electronic units. The above described electronic units further provide umbrella like shuttering mechanisms (i.e., fixed plate 62 and movable plate 54 or first plate 106 and second plate 108) near the top of the electronic units. In these embodiments, the shuttering mechanisms have at least two positions; one position where a majority of the holes line up and one position where a majority of the holes do not line up. The shuttering mechanisms are controlled to one of the two positions based on the requirements of the installation of the electronic unit.

Therefore, when forced air cooling is available in an installation and there is no fluid requirement the shuttering mechanism is set to the open position, where the majority of holes are aligned. When the installation of the electronic unit includes an operating near fluids requirement, the shuttering mechanism is set to the closed position, where the sets of holes are not aligned. When the installation of the electronic unit includes an operating near fluids requirement but, with an exception such as at elevated temperatures, the exception is sensed and hole alignment is applied appropriately. Specifically, extreme temperatures may be sensed and activated mechanically through bi-metal methods or electronically through a temperature sensor and solenoid.

As described above, the shuttering mechanisms include two plates with holes in each plate in a similar pattern. In certain embodiments, the plates are free to move relative to one another in one direction and are constrained in the other two orthogonal directions. This arrangement allows the holes in the plates to be placed in one of two positions; one where the holes line up (open) and one where they do not (closed). As further described above, the position of open or closed is controlled by a mechanism such as a solenoid or other mechanical or electromechanical means. It should be noted that embodiments also exist where the holes in the respective plates are not formed in similar patterns. In such embodiments, the benefits above described are obtained when the movable plate is moved to a first position where more of the holes in the respective plates align than do not align, and when the movable plate is moved to a second position where more of the holes in the respective plates do not align than do align. In other embodiments, a single hole in one plate can be sized to align with multiple holes in the other plate. Also, installations of more than two plates are contemplated.

There are advantages for both passive cooling and forced air cooling of electronic equipment. The above described embodiments provide benefits of each in a single electronic unit chassis design while also helping to prevent fluid entry into the electronic unit.

While the invention has been described in terms of various specific embodiments, those skilled in the art will recognize that the invention can be practiced with modification within the spirit and scope of the claims.

1. A cooling apparatus for an electronic unit comprising:
a generally planar first plate having holes formed therethrough;
a generally planar second plate having holes formed therethrough; and
a controlling mechanism operable to move said first plate with respect to said second plate, said mechanism operable to cause said first plate to move to a first position being where more holes in said first plate and said second plate are substantially aligned than not aligned, said mechanism operable to cause said first plate to move to a second position being where more holes in said first plate and said second plate are not aligned than are substantially aligned.

2. A cooling apparatus according to claim 1 wherein said second plate forms a top portion of a chassis for the electronic unit.

3. A cooling apparatus according to claim 1 wherein said first plate and said second plate are generally parallel to one another.

4. A cooling apparatus according to claim 1 wherein said first plate is free to move with respect to said second plate in one direction and constrained with respect to said second plate in other orthogonal directions.

5. A cooling apparatus according to claim 4 wherein said first plate comprises side walls and protrusions extending inward from said side walls, said protrusions engaging the electronic unit.

6. A cooling apparatus according to claim 1 wherein the holes in said first plate and said second plate are surrounded by conical protrusions.

7. A cooling apparatus according to claim 1 wherein said controlling mechanism controls a position of said first plate based on an input from a sensor.

8. A cooling apparatus according to claim 1 wherein said controlling mechanism comprises one or more of a solenoid, mechanical levers, a spring-loaded device, and a temperature controlled device.

9. A cooling apparatus according to claim 1 wherein said first plate and said second plate are configured with a substantially similar pattern of holes formed therethrough.

10. A chassis for an electronic unit comprising:
a top having holes formed therethrough; and
a generally planar plate movably mounted with respect to said top in said chassis, said plate substantially parallel to said top and having holes formed therethrough.

11. A chassis according to claim 10 wherein said plate is movable to a first position where more of the holes in said top and said plate are aligned than are not aligned, and movable to a second position where more of the holes in said top and said plate are not aligned than are aligned.

12. A chassis according to claim 10 wherein the holes in said top and said plate are surrounded by conical protrusions.

13. A chassis according to claim 10 further comprising a controlling mechanism operable to move said planar plate with respect to said top.

14. A chassis according to claim 10 wherein said controlling mechanism comprises one of a manual control, a solenoid, a switch, a spring-loaded device, and a temperature controlled device.

15. A chassis according to claim 9 wherein said planar plate is free to move with respect to said top in one direction and constrained with respect to said top in other orthogonal directions.

16. A chassis according to claim 15 wherein said planar plate comprises side walls and protrusions extending inward from said side walls, said protrusions engaging said chassis.

17. A chassis according to claim 15 wherein said planar plate and said top are configured with a substantially similar pattern of holes therethrough.

18. A method for constructing a chassis for an electronic unit that is compatible for active cooling, passive cooling and protected from ingress of fluids, said method comprising:
forming holes in a top of the chassis;
forming holes in a plate; and
movably mounting the plate above, and substantially parallel to the top of the chassis, the mounting including at least one position where more of the holes in the plate and the top substantially align with one another than do not align and at least one position where more of the holes do not substantially align with one another than do substantially align.

19. A method according to claim 18 further comprising:
forming a protrusion around each individual hole in the top of the chassis; and
forming a protrusion around each individual hole in the plate to be mounted above the chassis.

20. A method according to claim 18 further comprising configuring the electronic unit with a controlling mechanism, the controlling mechanism operable to move the plate with respect to the top of the chassis for substantial alignment and non-alignment of the holes formed in the top of the chassis and the plate mounted above.

21. A method according to claim 20 movably mounting the plate comprises:
forming channels in sides of the chassis;
configuring the plate with side walls and inward facing protrusions; and
engaging the inward facing protrusions with the channels.
